(19) United States
(12) Patent Application Publication
(10) Pub. No.: US 2013/0313952 A1
(43) Pub. Date: Nov. 28, 2013

(54) REMOVABLE CARRIER FOR A HARD DISK DRIVE

(71) Applicant: CHUN-HSIEN WU, New Taipei City (TW)

(72) Inventor: CHUN-HSIEN WU, New Taipei City (TW)

(21) Appl. No.: 13/746,315

(22) Filed: Jan. 22, 2013

(30) Foreign Application Priority Data
May 25, 2012 (TW) 101210041

(51) Int. Cl. H05K 7/14; H05K 5/02

(52) U.S. Cl. CPC H05K 7/14; H05K 5/0256
USPC 312/223.2

(57) ABSTRACT

The present invention provides an improved removable carrier for a hard disk drive, comprising an outer supporting frame having at least one removable stand; characterized in that: two lateral sides of the removable stand comprise at least one integrally formed clamping device having at least one attachment portion extended therefrom and for the securement of the removable stand thereon; the clamping device comprises an upper clamping portion having a connecting portion arched downward on one side thereof and extended therefrom; the connecting portion comprises a lower clamping portion arched and extended corresponding to the upper clamping portion; the clamping device comprises at least one upper and lower securement portions having an elastic clamp at a location of the upper and lower clamping portions. The integrally formed clamping device can advantageously clamp onto the outer supporting frame and merits of having a secured structure with reduced labor and costs are achieved.

### TECHNICAL FIELD OF THE INVENTION

The present invention is related to an improved removable carrier for a hard disk drive, in particular, to an improved removable carrier for a hard disk drive capable of providing an effective securement of the hard disk drive with reduced assembly labors, materials and costs.

### DESCRIPTION OF THE PRIOR ART

Conventional removable carriers for hard disk drives mostly adapt the design utilizing two-piece type of clamping devices provided on two sides of the removable carriers. However, as the clamping devices of such conventional removable carriers require the use of screws or bolts to secure such two-piece type of clamping devices, they often require greater assembly labors and costs during the manufacturing thereof. In addition, the precision and structural stability of the clamping devices of such conventional carriers achievable are too much lower; therefore, there is a need for improvement.

### SUMMARY OF THE INVENTION

A primary objective of the present invention is to overcome the drawbacks of great labors and costs required by conventional two-piece type of clamping device such that the securement precision and structural stability of the clamping device can be effectively improved with reduced labor and costs and such that the overall practical usability of the device is enhanced.

To achieve the abovementioned objective, the present invention provides an improved removable carrier for a hard disk drive (1), comprising an outer supporting frame having at least one removable stand provided therein, characterized in that: two lateral sides of the removable stand comprise at least one clamping device integrally formed as one piece and provided thereon respectively; the clamping device comprises at least one attachment portion extended therefrom and provided for the removable stand to be secured thereon; and the clamping device comprises an upper clamping portion defined thereon; the upper clamping portion comprises a connecting portion arched downward on one side of the upper clamping portion and extended therefrom; and the connecting portion further comprises a lower clamping portion arched and extended to a location corresponding to the upper clamping portion; wherein the clamping device comprises at least one upper and lower securement portions having an elastic clamp defined at a location of the upper and lower clamping portions respectively. In addition, it is advantageous that the removable stand comprises an opening handle pivotally attached thereto; and wherein the opening handle comprises a sliding abutment member arranged at a location of the removable stand pivotally attached thereto and provided for locking the sliding abutment member onto the outer supporting frame. Based on the aforementioned structure of the removable carrier for a hard drive disk, the integrally formed clamping device is able to utilize the upper and lower clamping portions to clamp onto the outer supporting frame to form a stable structure. Furthermore, as the clamping device can be manufactured via a press forming process, the overall labor and costs are effectively reduced in addition to the utilization of the upper and lower securement portions of the device to form firm a securement between components. Therefore, the removable carrier for a hard disk drive of the present invention can be advantageously provided to be of the merits of having a stable structure with reduced labor and costs.

### BRIEF DESCRIPTION OF THE DRAWINGS

FIG. 1 is a perspective view of an assembly of a preferred embodiment of the present invention;

FIG. 2 is an exploded view of the preferred embodiment of the present invention;

FIG. 3 is a partially enlarged view of the preferred embodiment of the present invention;

FIG. 4 is an illustration showing the clamping mechanism of the preferred embodiment of the present invention;

FIG. 5 is an illustration showing a first opening mechanism of the preferred embodiment of the present invention; and

FIG. 6 is an illustration showing a second opening mechanism of the preferred embodiment of the present invention.

### DETAILED DESCRIPTION OF THE PREFERRED EMBODIMENTS

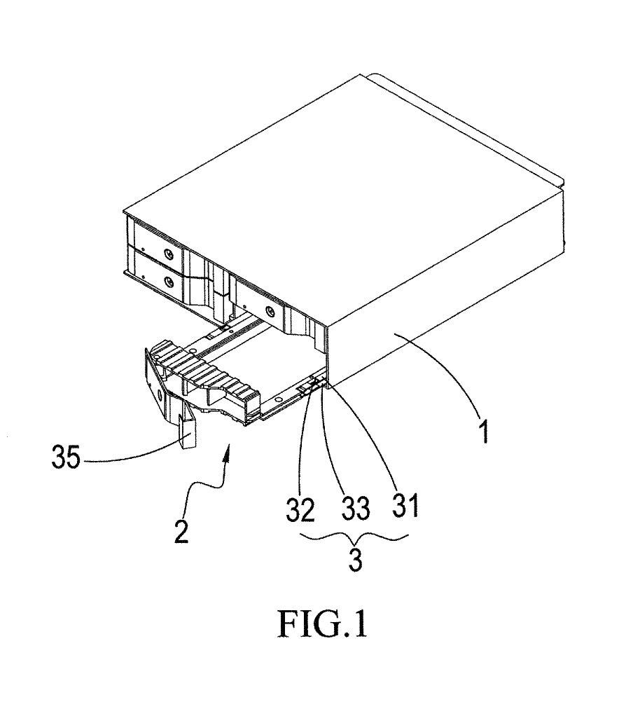

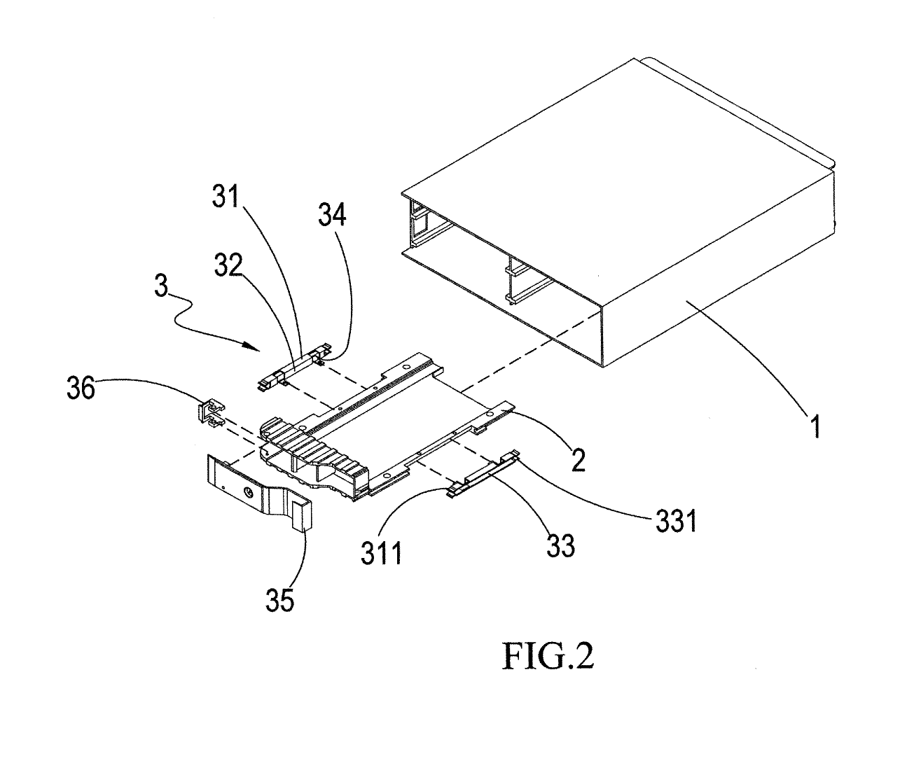

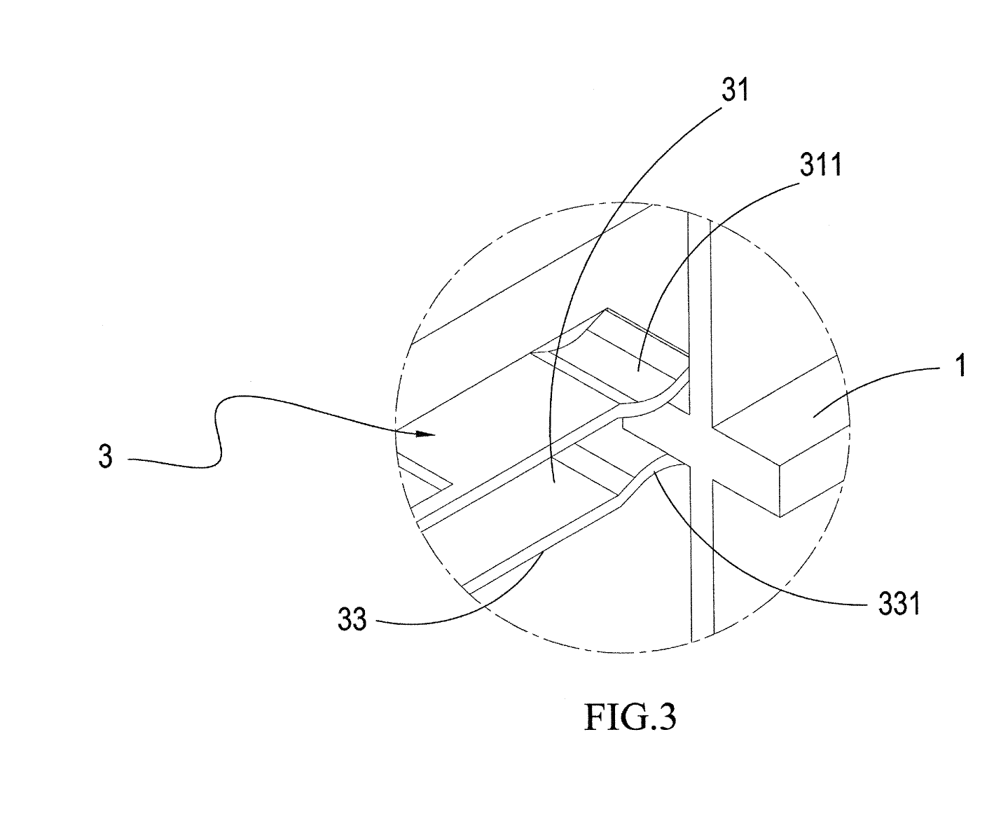

Please refer to FIG. 1, FIG. 2 and FIG. 3, showing a perspective view of an assembly of the present invention, an exploded view and a partially enlarged view of the present invention respectively. As shown in the figures, an improved removable carrier for a hard disk drive (1) of the present invention comprises an outer supporting frame 1 having at least one removable stand 2 provided therein and is characterized in that: two lateral sides of the removable stand 2 comprise at least one clamping device 3 integrally formed as one piece and provided thereon respectively; the clamping device 3 comprises at least one attachment portion 34 extended therefrom and provided for the removable stand 2 to be secured thereon; and the clamping device 3 comprises an upper clamping portion 31 defined thereon; the upper clamping portion 31 comprises a connecting portion 32 arched downward on one side of the upper clamping portion 31 and extended therefrom; and the connecting portion 32 further comprises a lower clamping portion 33 arched and extended to a location corresponding to the upper clamping portion 31; wherein the clamping device 3 comprises at least one upper securement portion 311 and lower securement portion 331 having an elastic clamp defined at a location of the upper clamping portion 31 and the lower clamping portion 33 respectively. In addition, it is advantageous that the removable stand 2 comprises an opening handle 35 pivotally attached thereto; and wherein the opening handle 35 comprises a sliding abutment member 36 arranged at a location of the removable stand 2 pivotally attached thereto and provided for locking the sliding abutment member 36 onto the outer supporting frame 1.

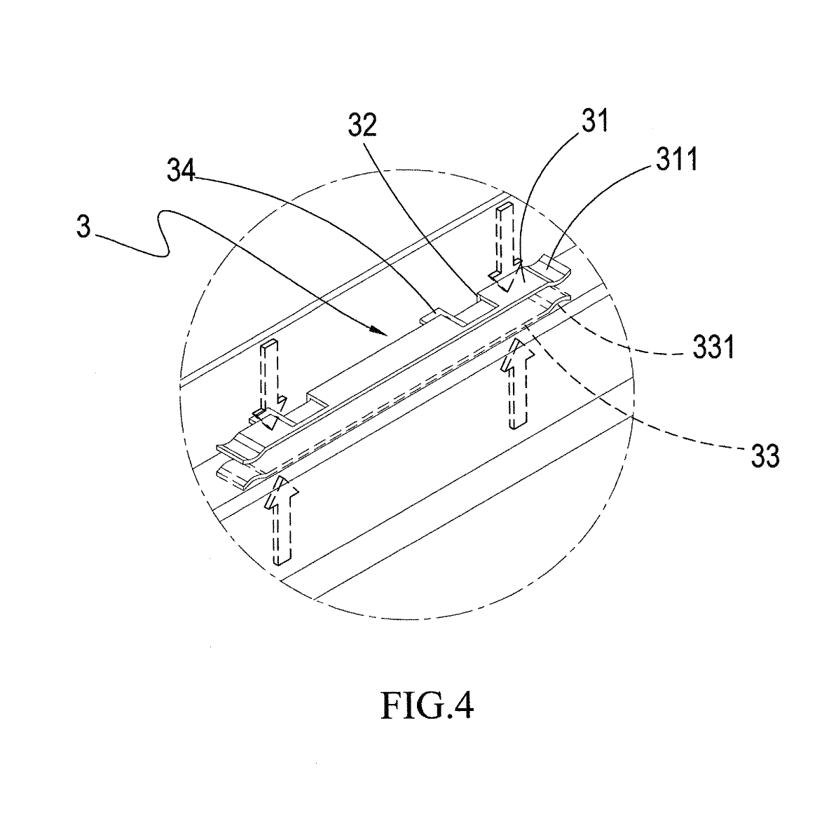

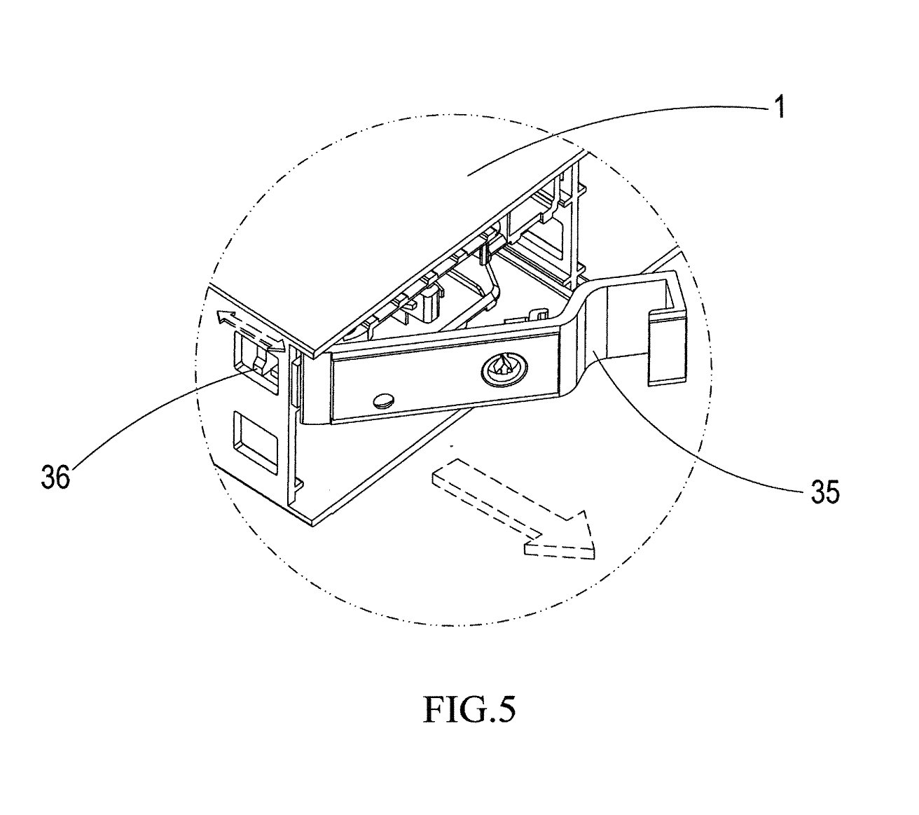

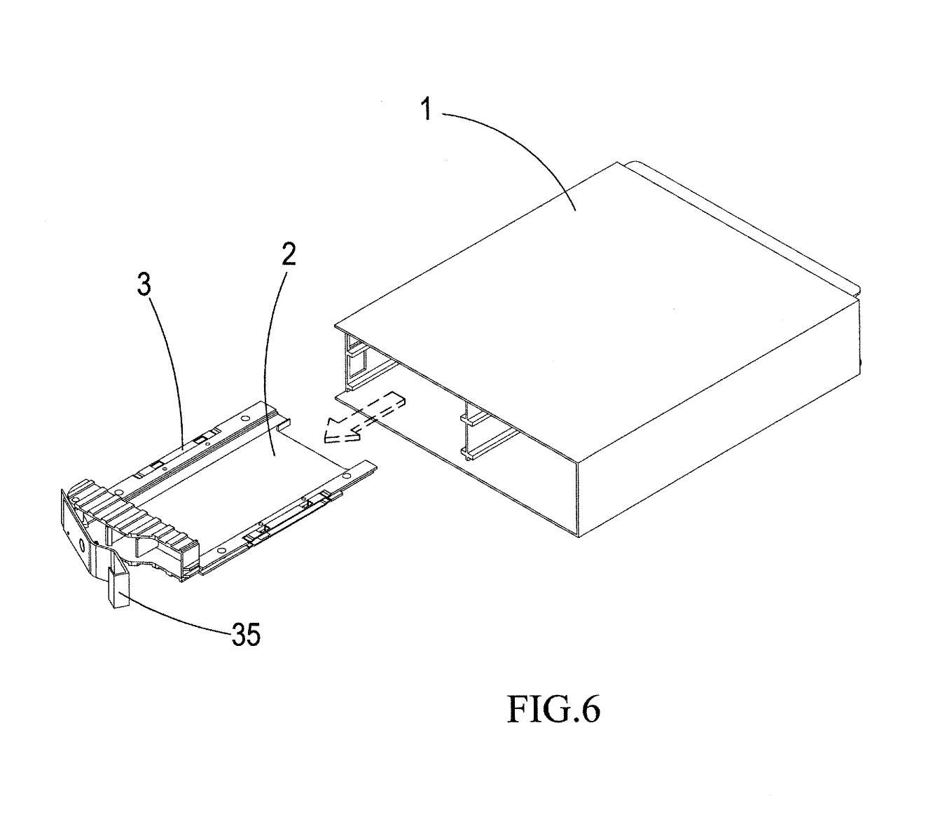

Based on the aforementioned structural design and assembly of the removable carrier for a hard disk drive of the present invention, the following describes an exemplary operation mechanism of the present invention. Please refer to FIG. 1, FIG. 3, FIG. 4, FIG. 5 and FIG. 6, showing the perspective of the assembly of the present invention, the partially enlarged view, the clamping mechanism, the first opening mechanism and the second opening mechanism of the removable carrier of the present invention. As shown in the figures, the clamping device 3 utilizes the attachment portion 34 for the securement onto the removable stand 2 such that in addition to the securement being provided, it can also provide necessary buffer during vibrations of the structure. As the upper clamping portion 31, the connecting portion 32 and the lower clamping portion 33 are integrally formed as one piece, the manufacturing of these parts can be of significantly simplified with reduced procedures and costs while allowing these parts to cooperate with the upper securement portion 311 and the lower securement portion 331 for effective abutment and locking. In addition, with the mechanism of the opening handle 35 and the sliding abutment member 36 provided, the removal of the opening and closing switch is facilitated such that the attachment operation of the removable stand 2 onto the outer supporting frame 1 can be achieved with greater ease.

In view of the above along with the accompanied drawings, it can be understood that the present invention posses at least the following merits over conventional arts:

1. As the attachment portion 34 is secured onto the removable stand 2, it not only provides necessary securement thereto but also buffers during vibrations of the device;

2. By integrally forming the upper clamping portion 31, the connecting portion 32 and the lower clamping portion 33 as one piece, the manufacturing process is advantageously simplified with reduced procedure and costs while allowing their cooperation with the upper securement portion 311 and the lower securement portion 331 to effectively achieve necessary abutment therebetween; and

3. With the mechanism provided by the opening handle 35 and the sliding abutment member 36, the removal of the opening and closing switch is facilitated such that the attachment operation of the removable stand 2 onto the outer supporting frame 1 can be achieved with greater ease.

What is claimed is:

1. An improved removable carrier for a hard disk drive, comprising an outer supporting frame having at least one removable stand provided therein, characterized in that:
two lateral sides of said removable stand comprise at least one clamping device integrally formed as one piece and provided thereon respectively;
said clamping device comprises an upper clamping portion defined thereon; said upper clamping portion comprises a connecting portion arched downward on one side of said upper clamping portion and extended therefrom; and said connecting portion further comprises a lower clamping portion arched and extended to a location corresponding to said upper clamping portion.

2. The improved removable carrier for a hard disk drive according to claim 1, wherein said clamping device comprises at least one attachment portion extended therefrom and provided for said removable stand to be secured thereon.

3. The improved removable carrier for a hard disk drive according to claim 1, wherein said clamping device comprises at least one upper securement portion having an elastic clamp defined at a location of said upper clamping portion.

4. The improved removable carrier for a hard disk drive according to claim 1, wherein said clamping device comprises at least one lower securement portion having an elastic clamp defined at a location of said lower clamping portion.

5. The improved removable carrier for a hard disk drive according to claim 1, wherein said removable stand comprises an opening handle pivotally attached thereto.

6. The improved removable carrier for a hard disk drive according to claim 5, wherein said opening handle comprises a sliding abutment member arranged at a location of said removable stand pivotally attached thereto and provided for locking said sliding abutment member onto said outer supporting frame.
